(19) United States
(12) Patent Application Publication
(10) Pub. No.: US 2026/0209973 A1
(43) Pub. Date: Jul. 23, 2026

(54) METHOD FOR SETTING AN ELECTROLYSER

(71) Applicant: Robert Bosch GmbH, Stuttgart (DE)

(72) Inventors: Christian Rinkenburger, Hermaringen (DE); Patrick Pascher, Korntal-Muenchingen (DE)

(21) Appl. No.: 19/157,842

(22) PCT Filed: Feb. 14, 2024
(86) PCT No.: PCT/EP2024/053696

§ 371 Date: Oct. 17, 2025

(30) Foreign Application Priority Data
Feb. 20, 2023 (DE) 10 2023 201 416.5

(51) Int. Cl. C25B 15/023; C25B 15/021; G06F 30/27

(52) U.S. Cl. CPC C25B 15/023; C25B 15/021; G06F 30/27

(57) ABSTRACT

The present invention relates to a method (100) for setting an electrolyzer.

The method (100) comprises:
determining (101) a plurality of state characteristic values of a cell stack of the electrolyzer based on cell voltages determined for various operating temperatures of the cell stack at a predefined operating point,
determining (103) at least one curve (201, 203, 205) of the state characteristic values over various operating temperatures for a predefined service life,
selecting (105) the operating temperature at which the curve (201, 203, 205) of the state characteristic values is at a maximum,
setting (107) the selected operating temperature for operating the electrolyzer.

### BACKGROUND

The presented invention relates to a method for setting an electrolyzer, an electrolyzer, a computing unit, and a software product.

Electrolyzers are electrochemical energy converters used, for example, to provide hydrogen.

An important criterion for an electrolyzer is the overall efficiency during time of operation. During operation of an electrolyzer, there is varying degradation of cells in a cell stack of the electrolyzer, depending on respective selected operating parameters, such as temperature, current density, etc.

In particular, the temperature in the cell stack has a major impact on the overall efficiency of the electrolyzer throughout its service life. A higher temperature increases the efficiency of the electrolyzer, while higher temperatures simultaneously have an accelerating effect on the aging process of the electrolyzer cell stack, thereby decreasing the efficiency of the cell stack over its useful life.

Accordingly, an optimal operating point must be found during the service life of the cell stack, which optimally matches the efficiency and the aging of the cell stack, since both variables are dependent on the operating temperature.

The aging process of a cell stack is complex and depends on many parameters, such as the operating temperature, the temperature distribution within the cell stack, the load curve, respective manufacturing tolerances, electrical conductivity of respective reactants, operating pressures, etc.

As a result, an optimal operating point that ensures the maximum overall efficiency over the operating life of an electrolyzer cannot be determined in a trivial manner. Due to the complex aging process, which is also determined based on manufacturing tolerances even under identical operating conditions, one and the same operating point cannot be optimally selected for different electrolyzers or different modules of an electrolyzer throughout the service life, with regard to the overall efficiency.

### SUMMARY

In the context of the invention presented, a method for setting an electrolyzer, an electrolyzer, a computing unit and a software product are presented. Further features and details of the invention arise from the respective dependent claims, the description, and the drawings. In this context, features and details described in connection with the method according to the invention clearly also apply in connection with the electrolyzer according to the invention and/or the computing unit according to the invention as well as the software product according to the invention, and respectively vice versa so that, with respect to the disclosure, mutual reference to the individual aspects of the invention is or can always be made.

The invention presented serves, in particular, to operate an electrolyzer in an energy-efficient manner throughout its useful life.

Therefore, according to a first aspect of the invention presented, a method for setting an electrolyzer is presented.

The method presented includes determining a plurality of state characteristic values of a cell stack of the electrolyzer based on cell voltages determined for different operating temperatures of the cell stack at a predefined operating point, determining at least one curve of the state characteristic values over different operating temperatures for a predefined service life, selecting the operating temperature, at which the curve of the state characteristic values is at a maximum and setting the selected operating temperature for operating the electrolyzer.

In the context of the invention presented, a state characteristic value is to be understood as a value that quantifies energy efficiency of a cell stack of an electrolyzer, in particular in relation to its service life.

In the context of the invention presented, an operating temperature is to be understood as a temperature that is predominantly present the cell stack of an electrolyzer during normal operation, i.e., potentially with short deviations.

A state characteristic value can be determined mathematically by means of a plurality of different calculation methods. For example, the state characteristic value can be determined as a quotient of a higher heating value (U_{HHV}) and a cell voltage (U_{Cell}) according to formula (1).

$${η}_{Stack} = \frac{{U}_{HHV}}{{U}_{cell}} \qquad ( 1 )$$

The efficiency of the stack (η_{stack}) can be determined from the cell voltage by converting the minimally required reaction enthalpy (A) for hydrogen electrolysis (Higher Heating Value γ=285.8
kJ/mol) to a voltage (U_{HHV}) using the Faraday constant (F≈96485 C/mol). The ratio of minimally required reaction enthalpy (A) to the actual required reaction enthalpy
( ) corresponds to the efficiency of the stack in relation to the higher heating value.

In this case, the relationship according to Formula (2) applies

$${U}_{HHV} = \frac{Δ H}{2 F} = 1 , 481 V \qquad ( 2 )$$

The current/voltage characteristic curves of a cell stack shift towards higher voltages, i.e., the efficiency decreases, through aging effects over the useful life of the cell stack. Inter alia, the operating temperature, temperature distribution within the stack, the load curve (static and dynamic), manufacturing tolerances, electrical conductivity of the water, operating pressures, etc. affect the aging of the cell stack over time (t), so the following applies:

$${U}_{C e l l} = {f}_{IV} ( {i}_{D ens} , {T}_{S tck} , {p}_{A nde} , Δ {p}_{S tck} , Δ {T}_{Stck} , t … ) \to {η}_{S t a c k} = f ( {i}_{D ens} , {T}_{S tck} , {p}_{A nde} , Δ {p}_{S tck} , Δ {T}_{S t c k} , t … )$$

Starting from a current cell voltage (U_{Cell, Actual}), the future cell voltage (U_{Cell,forecast}) can be concluded by taking into account the aging effect or an assumption for the aging effect (U_{Cell, Age}), so that:

$${U}_{C ell , Actua l ( iDens , TStck , t )} = {U}_{C ell , Actua l ( iDens , TStck )} + {U}_{C ell , Ag e ( TStck , t )}$$

$$and$$

$${η}_{S tack , forecast ( iDens , TStck , t )} = \frac{{U}_{HHV}}{{U}_{Cell , forecas t ( iDens , TStck , t )}}$$

Now, it is important to determine an operating temperature that finds an optimal balance between (temporary) efficiency gains by means of a higher temperature and the increased aging speed, depending on the operating point and the desired operating time. For this purpose, for example, for a predefined operating point (i_{Dens}) and different operating temperatures (T_{Stack}), the average integral under the efficiency (η_{Stack, Lifetime}) can be calculated via the operating time (toper) up to the target operating time (t_{Target}) according to Formula (3).

$${η}_{S t ack , Lifetime} = {\int }_{0}^{{t}_{T a r g e t}} \frac{{η}_{S t ack , forecast} ( {i}_{D ens} , {T}_{S t ack} , {t}_{oper} )}{{t}_{T arget}} d {t}_{Oper} \qquad ( 3 )$$

The optimal operating temperature results for a certain operating time and operating point, i.e., according to formula (4)

$${T}_{Stack , Opt} = \begin{matrix}max \\ {T}_{Stack}\end{matrix} ( {η}_{S tack , Lifetime} ( {i}_{D ens} , {T}_{Stack} , {t}_{Target} ) ) \qquad ( 4 )$$

Once the optimal operating temperature is determined, it may be set for the respective electrolyzer.

The cell voltages (_{Actual}) provided according to the present invention can be measured, for example, by means of a voltage measuring device.

It is conceivable that a plurality of curves of the state characteristic values are determined over various operating temperatures for a plurality of different predefined service lives, in particular for a predefined operating point, and presented on a display.

For example, by representing a plurality of curves of state characteristic values determined over various operating temperatures for a plurality of different predefined service lives, a technician may select and set, for the corresponding electrolyzer, an operating temperature that results in a corresponding service life.

It may be contemplated that the state characteristic value mathematically maps an efficiency of the cell stack over the predefined service life.

It may further be contemplated that determining the plurality of state characteristic values, determining the at least one curve of the state characteristic values, selecting the operating temperature and setting the selected operating temperature is performed multiple times over the useful life of the electrolyzer, such that the set operating temperature dynamically adjusts to a state, a current state in particular, of the electrolyzer and, for example, settles upon a value or range of values over time. The current state may be different from a prior forecast.

It may further be conceivable that a mathematical model is used to determine the plurality of state characteristic values, wherein the mathematical model is formed based on operating parameters determined for the cell stack of the electrolyzer and/or a plurality of cell stacks of electrolyzers.

A mathematical model, formed based on a particular electrolyzer or module of an electrolyzer system, is specifically optimized for particular electrolyzer properties, whereas a mathematical model based on many electrolyzers or modules, is particularly robust with regard to measurement tolerances, and may be able to predict effects to be expected in the future, such as defects so that maintenance work can be scheduled.

It may further be conceivable that the mathematical model comprises a machine learner trained to associate respective operating parameters of a cell stack with a state characteristic value or a plurality of state characteristic values.

A machine learner, such as an artificial neural network, may be trained on predefined training data to automatically determine an optimal setting of an electrolyzer based on respective measured cell voltages.

It may further be conceivable that the mathematical model is executed locally on a computing unit of the electrolyzer.

A locally executed method allows direct and automatic setting of the electrolyzer by itself.

It may further be conceivable that the mathematical model is executed on a central server, wherein the central server communicatively connected to a plurality of electrolyzers.

A central server for executing the mathematical model allows for central control of a plurality of electrolyzers by adjusting the mathematical model.

According to a second aspect, the invention presented relates to an electrolyzer for providing hydrogen, wherein the electrolyzer comprises a computing unit configured to perform a method according to the first aspect of the invention. All of the advantages listed regarding the method for setting an electrolyzer according to the first aspect of the invention apply equally to the electrolyzer according to the second aspect of the invention.

According to a third aspect, the presented invention relates to a computing unit for setting a plurality of electrolyzers, wherein the computing unit is communicatively connected to the plurality of electrolyzers and configured to perform a method according to the first aspect of the invention and to set a respective selected operating temperature for a respective electrolyzer, in particular according to the second aspect of the invention.

In the context of the invention presented here, a computing unit is understood to mean a computer, a processor, a control device, or any other programmable circuit. In particular, the presented computing unit may be a central server communicatively connected to a plurality of electrolyzers and/or a plurality of modules of an electrolyzer. Alternatively, the computing unit may be in control unit locally integrated into an electrolyzer.

According to a fourth aspect, the proposed invention relates to a software product, wherein the software product comprises program code means which, when executed on a computing unit, configure the computing unit to perform a possible embodiment of the proposed method.

### BRIEF DESCRIPTION OF THE DRAWINGS

Further advantages, features, and details of the invention arise from the following description, in which exemplary embodiments of the invention are described in detail with reference to the drawings. In this context, the features mentioned in the claims and in the description can each be essential to the invention individually or in any combination.

### Shown are:

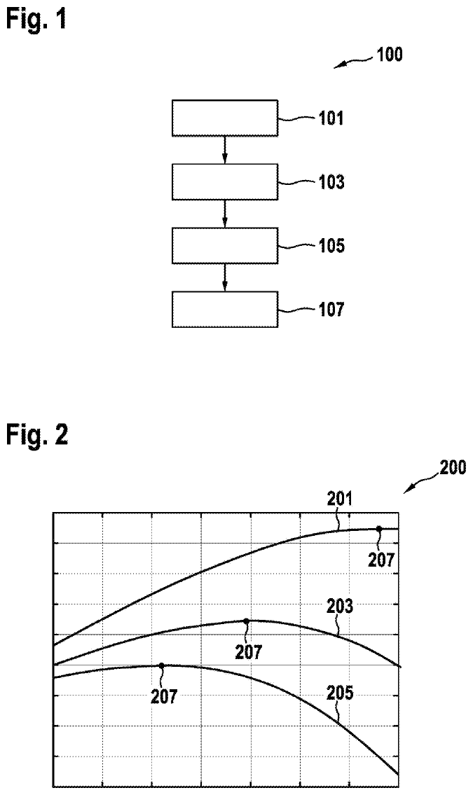

FIG. 1 a schematic illustration of a possible embodiment of the method presented for setting an electrolyzer.

FIG. 2 an overview of several curves of state characteristic values of a cell stack of an electrolyzer according to a possible embodiment of the method presented.

### DETAILED DESCRIPTION

In FIG. 1, a method 100 for setting an electrolyzer is shown.

Method 100 comprises a first determination step 101, in which a plurality of state characteristic values of a cell stack of the electrolyzer are determined based on cell voltages determined for various operating temperatures of the cell stack at a predefined operating point.

Furthermore, method 100 comprises a second determination step 103, in which at least one curve of the state characteristic values over various operating temperatures is determined for a predefined service life.

Furthermore, method 100 comprises a selection step 105, in which the operating temperature for which the curve of the state characteristic values is at a maximum is selected, and a setting step 107, in which the selected operating temperature is set for operating the electrolyzer.

FIG. 2 is a graph 200 with the x-axis showing the operating temperature and the y-axis showing a state characteristic value of a cell stack of an electrolyzer in the form of an average energy efficiency over the useful life in [%].

A first curve 201 corresponds to state characteristic values determined for a useful of 12 years.

A second curve 203 corresponds to state characteristic values determined for a useful life of 15 years.

A third curve 205 corresponds to state characteristic values determined for a useful life of 17 years.

The curves 201, 203 and 205 are respectively marked at their maximum with a marker 207, because at this point the state characteristic value is optimal, i.e., achieves an optimum efficiency for the respective useful life. Accordingly, an operating temperature may be selected at the location of the marked state characteristic values for the respective useful life and set for an electrolyzer.

1. A method for setting an electrolyzer,
the method comprising:
determining, via a computer, a plurality of state characteristic values of a cell stack of the electrolyzer based on cell voltages determined for various operating temperatures of the cell stack at a predefined operating point,
determining, via the computer, at least one curve of the state characteristic values over various operating temperatures for a predefined service life,
selecting, via the computer, the operating temperature at which the curve of the state characteristic values is at a maximum, and
setting, via the computer, the selected operating temperature for operating the electrolyzer.

2. The method according to claim 1,
further comprising
determining, via the computer, a plurality of curves of the state characteristic values over various operating temperatures for a plurality of different predefined service lives and presented on a display.

3. The method according to claim 1,
wherein
the state characteristic value mathematically maps an efficiency of the cell stack over the predefined service life.

4. The method according to claim 1,
wherein
determining the plurality of state characteristic values, determining the at least one curve of the state characteristic values, selecting the operating temperature, and setting the selected operating temperature are carried out multiple times during the service life of the electrolyzer.

5. The method according to claim 1,
wherein
a mathematical model is used to determine the plurality of state characteristic values, wherein the mathematical model is formed based on operating parameters determined for the cell stack of the electrolyzer and/or a plurality of cell stacks of electrolyzers.

6. The method according to claim 5,
wherein
the mathematical model comprises a machine learner trained to associate respective operating parameters of a cell stack with a state characteristic value.

7. The method according to claim 5,
wherein
the mathematical model is executed locally on a computer of the electrolyzer.

8. The method according to claim 5,
wherein
the mathematical model is executed on a central server, wherein the central server is communicatively connected to a plurality of electrolyzers.

9. An electrolyzer for providing hydrogen,
wherein the electrolyzer comprises a computer configured to:
determine a plurality of state characteristic values of a cell stack of the electrolyzer based on cell voltages determined for various operating temperatures of the cell stack at a predefined operating point,
determine at least one curve of the state characteristic values over various operating temperatures for a predefined service life,
select the operating temperature at which the curve of the state characteristic values is at a maximum, and
set the selected operating temperature for operating the electrolyzer.

10. A computer for setting a plurality of electrolyzers,
wherein the computer is configured to be communicatively connected to the plurality of electrolyzers and is configured to
determine a plurality of state characteristic values of a cell stack of each electrolyzer based on cell voltages determined for various operating temperatures of the cell stack at a predefined operating point,
determine at least one curve of the state characteristic values over various operating temperatures for a predefined service life,
select the operating temperature at which the curve of the state characteristic values is at a maximum, and
to set a respective selected operating temperature for a respective electrolyzer.

11. A non-transitory, computer-readable medium comprising instructions that when executed by a computer cause the computer to
determine a plurality of state characteristic values of a cell stack of an electrolyzer based on cell voltages determined for various operating temperatures of the cell stack at a predefined operating point,
determine at least one curve of the state characteristic values over various operating temperatures for a predefined service life,
select the operating temperature at which the curve of the state characteristic values is at a maximum, and
set the selected operating temperature for operating the electrolyzer.
